(19) United States
(12) Patent Application Publication
(10) Pub. No.: US 2025/0155804 A1
(43) Pub. Date: May 15, 2025

(54) PHOTORESIST COMPOSITION

(71) Applicant: TAIWAN SEMICONDUCTOR MANUFACTURING COMPANY, LTD., Hsinchu (TW)

(72) Inventors: Min-Hung TSAI, Changhua County (TW); Siao-Shan WANG, Tainan City (TW); Chen-Yu LIU, Kaohsiung City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/508,423

(22) Filed: Nov. 14, 2023

(51) Int. Cl. G03F 7/038; G03F 7/004; G03F 7/025; G03F 7/031; G03F 7/039; G03F 7/20

(52) U.S. Cl. CPC G03F 7/0382; G03F 7/0043; G03F 7/0048; G03F 7/025; G03F 7/031; G03F 7/0392; G03F 7/201

(57) ABSTRACT

A photoresist composition comprises a solvent and a polymer. The polymer is dissolved in the solvent. The photoresist composition further comprises a first additive. The first additive is dissolved in the solvent. The first additive is made of a core structure and one or more radical-active functional groups connected to the core structure.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of an exemplary method for patterning a target layer in accordance with some embodiments.

FIG. 2A is a cross-sectional view of a semiconductor device at various stages of the method of FIG. 1 in accordance with various aspects of the present disclosure.

FIG. 2B is an enlarged view of a region in FIG. 2A in some embodiments.

FIGS. 3A-3E are first additives in a photoresist composition of the photoresist layer corresponding to FIG. 2A in accordance with various aspects of the present disclosure.

FIGS. 4A-4F are first additives in a photoresist composition of the photoresist layer corresponding to FIG. 2A in accordance with various aspects of the present disclosure.

FIGS. 5-7 are cross-sectional views of a semiconductor device at various stages of the method of FIG. 1 in accordance with various aspects of the present disclosure.

FIGS. 8-11 are cross-sectional views of a semiconductor device in an intermediate stage of fabrication in accordance with some embodiments of the present disclosure.

FIG. 12A is a perspective view of the semiconductor device in an intermediate stage of fabrication in accordance with some embodiments of the present disclosure.

FIGS. 12B and 12C are cross-sectional views along line a1-a1 and line b1-b1 of FIG. 12A, respectively, in accordance with various aspects of the present disclosure.

FIGS. 13-16 are cross-sectional views of the semiconductor device in an intermediate stage of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

Modern fabrication of semiconductor devices primarily attributes to photolithography. Photoresists enable patterns to be precisely defined in nanoscale after exposure, followed by etching processes to transfer the patterns into a substrate or a target layer over a substrate. Accordingly, an ability of the photoresists is vital to prevent a failure of feature fidelity.

The present disclosure provides a photoresist composition including one or more first additives, and thus the photoresist layer can have enhanced etch resistance for the etch process.

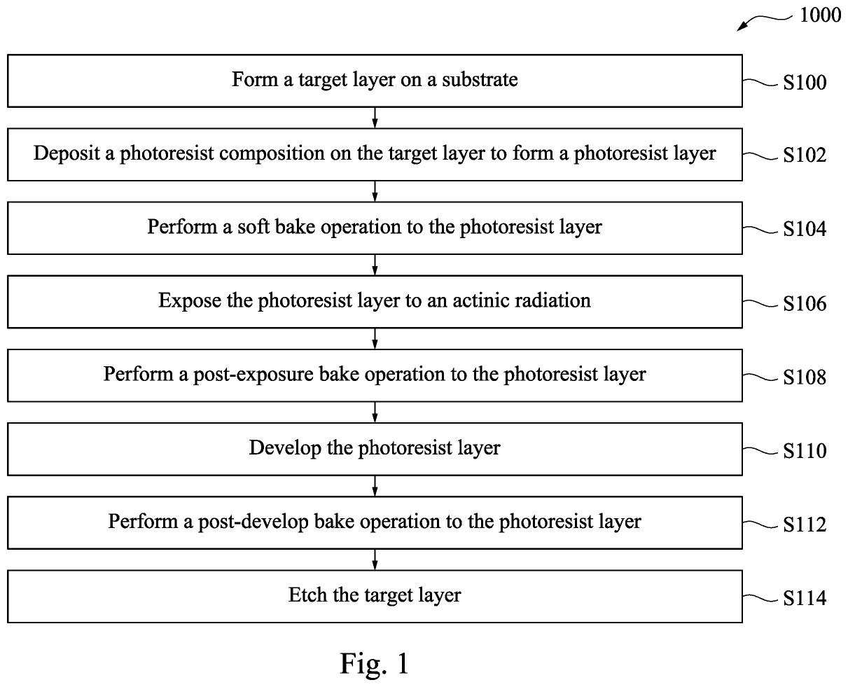

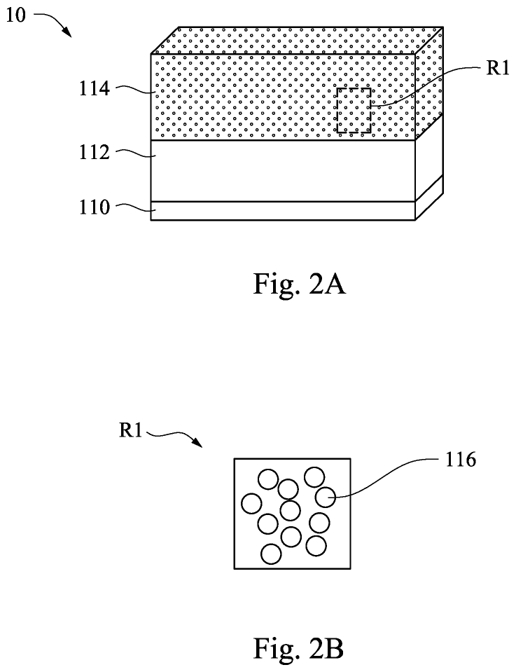

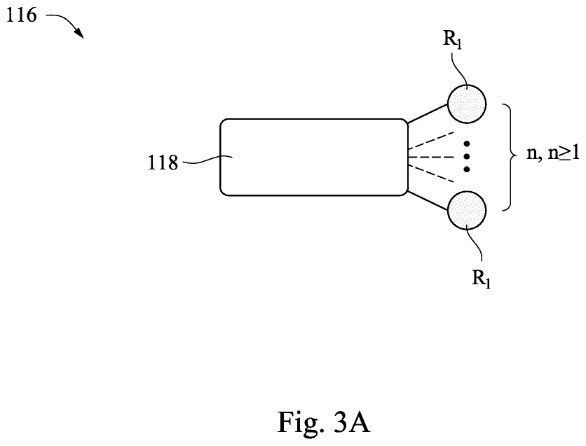

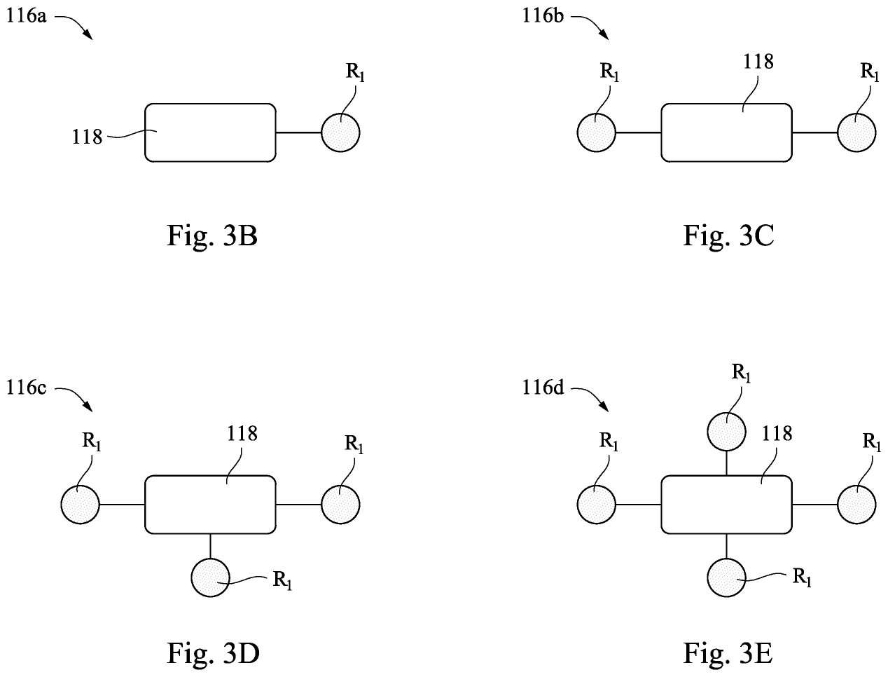

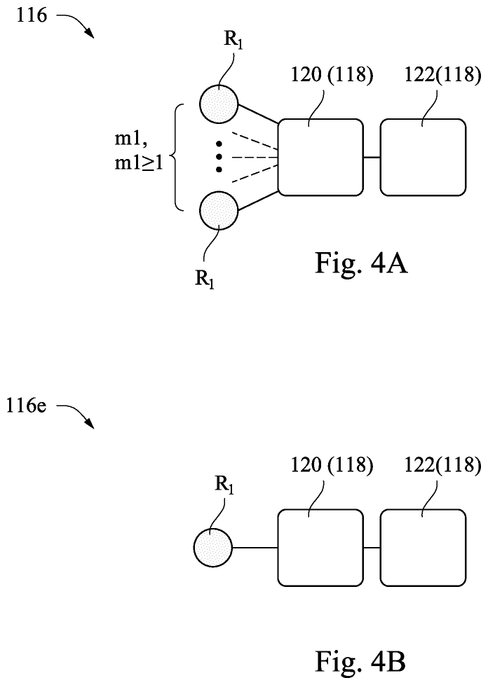

FIG. 1 is a flowchart of an exemplary method 1000 for patterning a target layer in accordance with some embodiments. FIG. 2A is a cross-sectional view of a semiconductor device at various stages of the method 1000 of FIG. 1 in accordance with various aspects of the present disclosure. FIG. 2B is an enlarged view of a region in FIG. 2A in some embodiments. FIGS. 3A-3E and 4A-4F are first additives in a photoresist composition of the photoresist layer corresponding to FIG. 2A in accordance with various aspects of the present disclosure. FIGS. 5-7 are cross-sectional views of a semiconductor device 10 at various stages of the method 1000 of FIG. 1 in accordance with various aspects of the present disclosure.

The method 1000 includes a relevant part of an entire manufacturing process. It is understood that additional operations may be provided before, during and after the operations shown by FIG. 1, and some of the operations described below can be replaced or eliminated for additional embodiments of the method. The order of the operations/processes may be interchangeable. The method 1000 includes fabrication of a semiconductor device. However, the fabrication of the semiconductor device is merely an example for describing the manufacturing process according to some embodiments of the present disclosure.

The method 1000 begins at operation S100 in which the operation S100 includes forming a target layer on a substrate. With reference to FIGS. 1 and 2A, in some embodiments of the operation S100, a target layer 112 to be patterned is formed on a substrate 110. For example, the target layer 112 may be formed by an acceptable deposition process, such as chemical vapor deposition (CVD), physical vapor deposition (PVD), atomic layer deposition (ALD), spin coating process, or the like. The substrate 110 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

In some embodiments, the substrate 110 is a silicon substrate doped with a p-type dopant such as boron (for example a p-type substrate). Alternatively, the substrate 110 could be another suitable semiconductor material. For example, the substrate 110 may be a silicon substrate that is doped with an n-type dopant such as phosphorous or arsenic (an n-type substrate). The substrate 110 could include other elementary semiconductors such as germanium and diamond. The substrate 110 could optionally include a compound semiconductor and/or an alloy semiconductor. Further, the substrate 110 could include an epitaxial layer (epi layer), may be strained for performance enhancement, and may include a silicon-on-insulator (SOI) structure.

In some embodiments, the target layer 112 is substantially conductive or semi-conductive. The electrical resistance may be less than about 10³ ohm-meter. In some embodiments, the target layer 112 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the target layer may contain Ti, Al, Co, Ru, TiN, WN₂, or TaN.

In some other embodiments, the target layer 112 contains a dielectric material with a dielectric constant in a range from about 1 to about 40. In some other embodiments, the target layer 112 contains Si, metal oxide, or metal nitride, where the formula is MX_{b}, wherein M is a metal or Si, and X is N or O, and wherein “b” is in a range from about 0.4 to 2.5. For example, the target layer 112 may contain SiO₂, silicon nitride, aluminum oxide, hafnium oxide, or lanthanum oxide.

The method 1000 then proceeds to operation S102 in which the operation S102 includes depositing a photoresist composition on the target layer to form a photoresist layer. With reference to FIGS. 1 and 2A, in some embodiments of the operation S102, a photoresist composition is deposited on the target layer 112 to form a photoresist layer 114. The photoresist composition deposited on the target layer 112 to form the photoresist layer 114 may be formed by spin coating process or deposition process. Reference is made to FIGS. 3A-3E. In some embodiments, the photoresist composition includes a solvent, a polymer (e.g., an organic polymer), and one or more first additives 116. Reference is made to FIGS. 2A, 2B and 3A-3E. The first additives 116 are configured to enhance an etch resistance of the photoresist layer 114 for accomplishment of extensive process window. Various examples of the first additives 116 are shown in FIGS. 3A-3E. In some embodiments, the first additives 116 are made of a core structure (also referred to as a linker) 118 and one or more radical-active functional groups R₁ connected to the core structure 118. For example, a number of the radical-active functional groups R₁ is n, in which n is an integer equal to or greater than 1. In FIG. 3B, a first additive 116a include the core structure 118 and one radical-active functional group R₁ connected (or bonded) to the core structure 118. In FIG. 3C, a first additive 116b includes the core structure 118 and two radical-active functional groups R₁ connected (or bonded) to the core structure 118. In FIG. 3D, a first additive 116c includes the core structure 118 and three radical-active functional groups R₁ connected (or bonded) to the core structure 118. In FIG. 3E, a first additive 116d includes the core structure 118 and four radical-active functional groups R₁ connected (or bonded) to the core structure 118.

In some embodiments, the core structure 118 may be a linear, branch, cyclic alkyl group, aromatic, electron-withdrawing and electron-donating moieties, or a combination thereof. In some embodiments, the radical-active functional groups R₁ may be a moiety including non-single bond, such as including double bonds, triple bonds, or a combination thereof. For example, the radical-active functional groups R₁ may be embedded in a linear, branch, and/or cyclic alkyl moieties.

In some embodiments, the first additives 116 of the photoresist composition may be represented by one of the following structures:

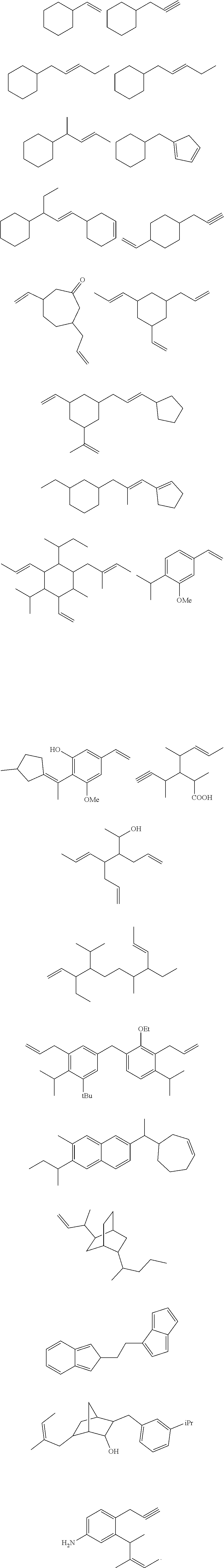

Reference is made to FIGS. 4A-4F. In some embodiments, the core structure 118 of the first additives 116 may be made of a cation 120 and an anion 122 connected (or bonded) to the anion 122. In other words, the first additives 116 may be made of the cation 120 and the anion 122 as a counterpart. Various examples of the first additives 116 are shown in FIGS. 4A-4F.

In some embodiments, the first additives 116 are made of the core structure (also referred to as a linker) 118 and one or more radical-active functional groups R₁. In FIG. 4A, in some embodiments, the one or more radical-active functional groups R₁ are connected to the cation 120 of the core structure 118. A number of the one or more radical-active functional groups R₁ is m1 in which m1 is an integer equal to 1 or greater than 1. For example, in FIG. 4B, m1 is equal to 1. That is, the first additive 116e has one radical-active functional group R₁ connected to the cation 120 of the core structure 118.

In FIG. 4C, in some embodiments, the one or more radical-active functional groups R₁ are connected to the anion 122 of the core structure 118. A number of the one or more radical-active functional groups R₁ is n1, in which n1 is an integer equal to 1 or greater than 1. For example, in FIG. 4D, n1 is equal to 1. That is, the first additive 116f has one radical-active functional group R₁ connected to the cation 120 of the core structure 118.

In FIG. 4E, in some embodiments, the one or more radical-active functional groups R₁ has a first group connected to the cation 120 of the core structure 118 and a second group connected to the anion 122 of the core structure 118. A number of the first group of the one or more radical-active functional groups R₁ is m2 in which m2 is an integer equal to 1 or greater than 1. A number of the second group of the one or more radical-active functional groups R₁ is n2 in which n2 is an integer equal to 1 or greater than 1. For example, in FIG. 4F, m2 is equal to 1, and n2 is equal to 1. That is, the first additive 116g has one radical-active functional group R₁ connected to the cation 120 of the core structure 118, and one radical-active functional group R₁ connected to the anion 122 of the core structure 118.

In some embodiments, the cation 120 is linear, branch, cyclic alkyl group, aromatic, electron-withdrawing and electron-donating moieties, or a combination thereof. In some embodiments, the anion 122 is linear, branch, cyclic alkyl group, aromatic, electron-withdrawing and electron-donating moieties, or a combination thereof. In some embodiments, the radical-active functional groups R₁ may be a moiety including multiple bonds, such as, double bonds, triple bonds, or a combination thereof. For example, the radical-active functional groups R₁ may be embedded in a linear, branch, and/or cyclic alkyl moieties.

In some embodiments, the first additives 116 of the photoresist composition made of the cation 120 and the anion 122 may be represented by one of the following structures:

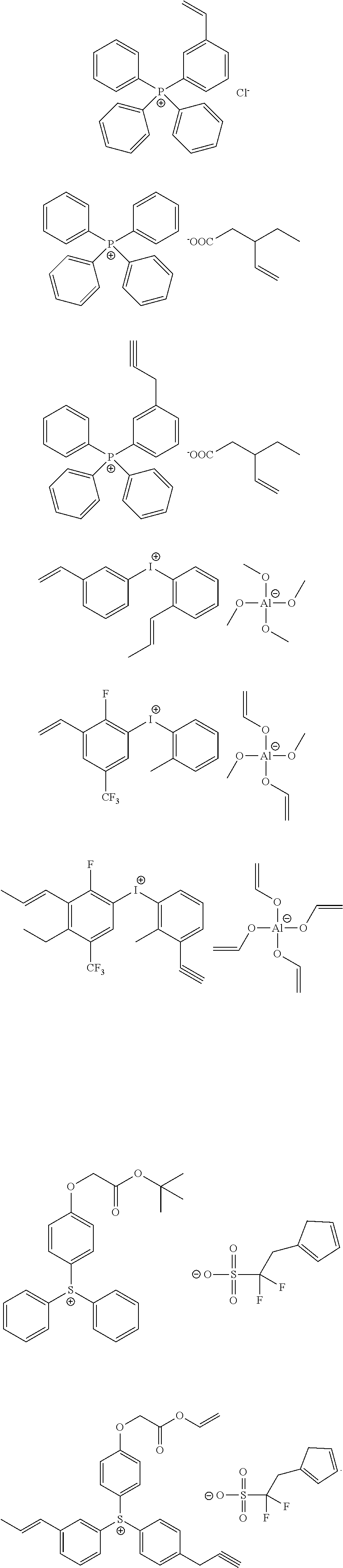

In some embodiments, the photoresist composition may include second additives different from the first additives. For example, the second additives may be quencher, photo-acid generator (PAG), chromophore, crosslinker, surfactant, the like, or a combination thereof. In some embodiments, the polymer of the photoresist composition includes a polymer backbone and an acid cleavable acid labile group (ALG) bonded to the polymer backbone. The PAG is configured to release an acid after a subsequent optical exposure (e.g., actinic radiation 124 in FIG. 5), and the acid will cleave the ALG in a post exposure baking (PEB) operation such that the polymer become more hydrophilic. The quencher is configured to neutralize excessive acids produced by the PAG after the subsequent optical exposure.

The method 1000 then proceeds to operation S104 in which the operation S104 includes performing a soft bake operation to the photoresist layer. With reference to FIGS. 1 and 2A, in some embodiments of the operation S104, a soft bake operation is performed to the photoresist layer 114 such that the solvent may partially evaporate.

The method 1000 proceeds to operation S106 in which the operation S106 includes exposing the photoresist layer to an actinic radiation. With reference to FIGS. 1 and 5, in some embodiments of the operation S106, the photoresist layer 114 is exposed to an actinic radiation 124. In some embodiments, the photoresist layer 114 is exposed to the actinic radiation 124 with an illumination wavelength which is substantially less than about 250 nm. F For example, the actinic radiation 124 may include at least one of the Kr, ArF, extreme ultraviolet (EUV) radiation, E-beam or the like. The photoresist layer 114 may include an exposed region and an unexposed region. The PAG may release acids after the actinic radiation 124.

The method 1000 proceeds to operation S108 in which the operation S108 includes performing a post-exposure bake operation to the photoresist layer. With reference to FIGS. 1 and 5, in some embodiments of the operation S108, a post-exposure bake operation is then performed to the photoresist layer 114. During the post exposure bake (PEB) operation, the base produced by the quencher and the acid produced by the PAG may diffuse in the photoresist layer 114. The ALG of the polymer is cleaved by the acids released by the PAG. After the acids cleave the ALG of the polymer, the polymer becomes more hydrophilic.

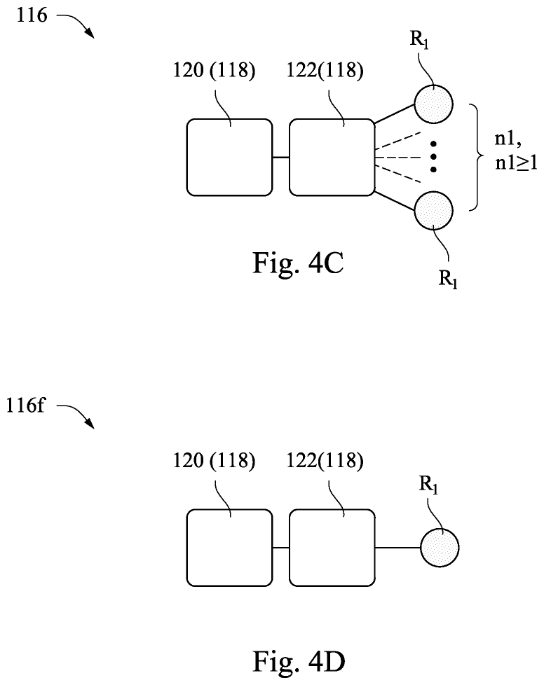

The method 1000 proceeds to operation S110 in which the operation S110 includes developing the photoresist layer. With reference to FIGS. 1 and 6, in some embodiments of the operation S110, the photoresist layer 114 is subsequently developed by applying a developer to the photoresist layer 114. In some embodiments, the developer can be a water-based solution or a solvent-based solution. For example, the water-based solution is a positive tone developer (PTD), such as a tetramethylammonium hydroxide (TMAH), and the solvent-based solution is a negative tone developer (NTD), such as n-butyl acetate (nBA).

The method 1000 proceeds to operation S112 in which the operation S112 includes performing a post-develop bake operation to the photoresist layer. With reference to FIGS. 1 and 6, in some embodiments of the operation S112, a post-develop bake operation is performed to the photoresist layer 114 to cure the photoresist layer 114.

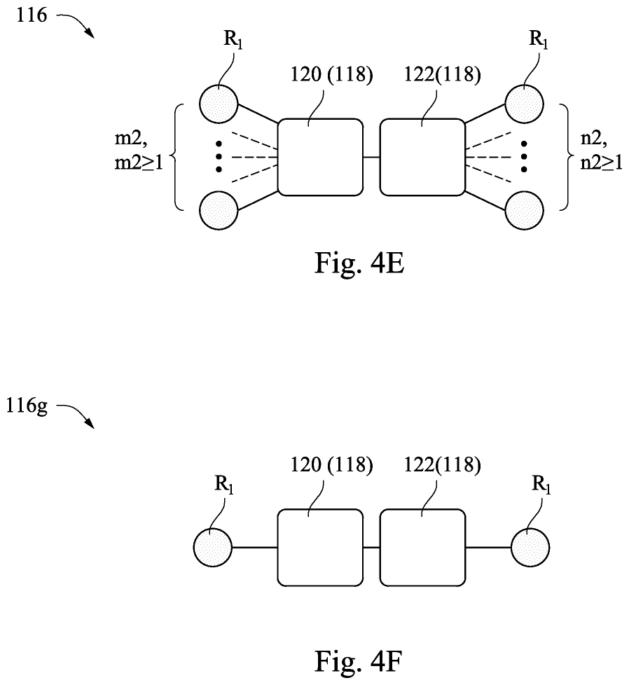

The method 1000 proceeds to operation S114 in which the operation S116 includes performing an etch process to the target layer. With reference to FIGS. 1 and 7, in some embodiments of the operation S116, an etch process is performed to the target layer 112 using the photoresist layer 114 as an etch mask, thus forming trenches 126 in the target layer 112. For example, the etch process is a dry etch process including a biased plasma etch process that uses a chlorine-based chemistry, CF₄, NF₃, SF₆, or the like. The dry etch process may be performed anisotropically. Due to the photoresist layer 114 deposited by the photoresist composition including the one or more first additives 116 (see FIG. 2B), the photoresist layer 114 can have enhanced etch resistance for the etch process. That is, during the etch process performed to the target layer 112, an undesired collapse or deformation of the photoresist layer 114 may be prevented. Therefore, the photoresist layer 114 can be prevented from failure of feature fidelity during the etch process, and an extensive process window can be accomplished.

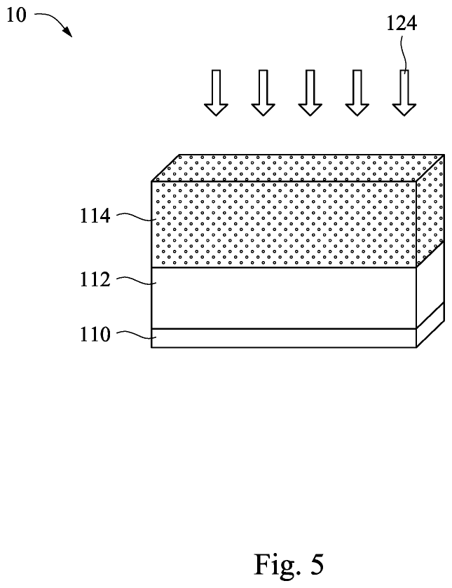

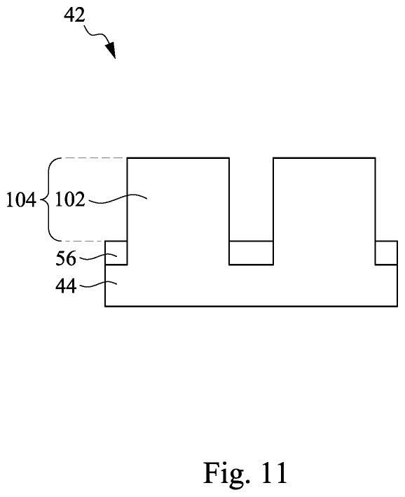

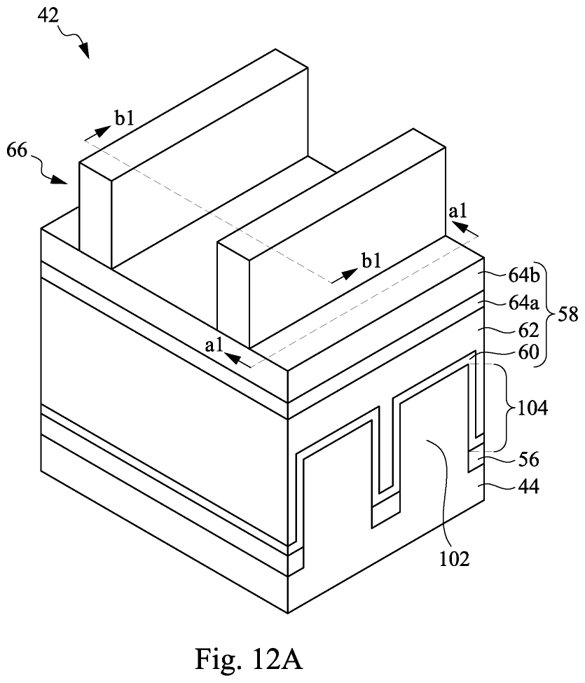

FIGS. 8-11 are cross-sectional views of a semiconductor device 42 in an intermediate stage of fabrication in accordance with some embodiments of the present disclosure. FIG. 12A is a perspective view of the semiconductor device 42 in an intermediate stage of fabrication in accordance with some embodiments of the present disclosure. FIGS. 12B and 12C are cross-sectional views along line a1-a1 and line b1-b1 of FIG. 12A, respectively, in accordance with various aspects of the present disclosure. FIGS. 13-16 are cross-sectional views of the semiconductor device 42 in an intermediate stage of fabrication in accordance with some embodiments of the present disclosure. Reference is made to FIG. 8. A photoresist layer 45 is formed on a substrate 44. The photoresist layer 45 and the substrate 44 are similar to the photoresist layer 114 and the substrate 110 in terms of composition as discussed previously with regard to FIGS. 2A-4F, and thus the description thereof is omitted herein.

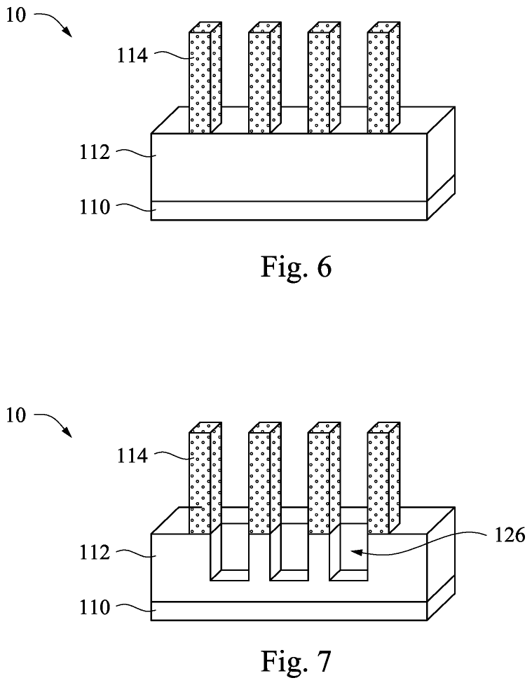

The photoresist layer 45 may be formed on the substrate 44 using multiple operations including the operations S102, S104, S106, S108, S110 and S112 in the method 1000 in FIG. 1. Therefore, the description thereof is omitted herein. Reference is made to FIG. 9. An etch process is performed to the substrate 44 using the photoresist layer 45 as an etch mask such that trenches 54 are formed in the substrate 44. In some embodiments, the etch process is similar to the operation S114, and thus the description thereof is omitted herein. As discussed previously with regard to FIGS. 2A to 4F, due to the photoresist layer deposited by the photoresist composition including the one or more first additives 116, the photoresist layer 45 can have enhanced etch resistance for the etch process. That is, during the etch process performed to the substrate 44, an undesired collapse or deformation of the photoresist layer 45 may be prevented. Therefore, the photoresist layer 45 can be prevented from failure of feature fidelity during the etch process, and an extensive process window can be accomplished.

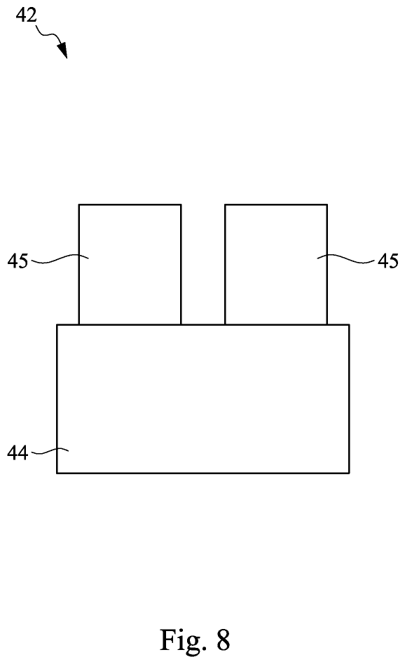

The photoresist layer 45 is removed after etching the substrate 44 by using a suitable photoresist stripper solvent or by a photoresist ashing operation. Isolation regions such as shallow trench isolation (STI) regions 56 may be formed on the substrate 44, filling into the trenches 54. The resulting structure in shown in FIG. 10.

The STI regions 56 may include a liner oxide (not shown). The liner oxide may be formed of a thermal oxide formed through a thermal oxidation of a surface layer of the substrate 44. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The STI regions 56 may also include a dielectric material over the liner oxide, and the dielectric material may be formed using flowable chemical vapor deposition (FCVD), spin-on coating, or the like.

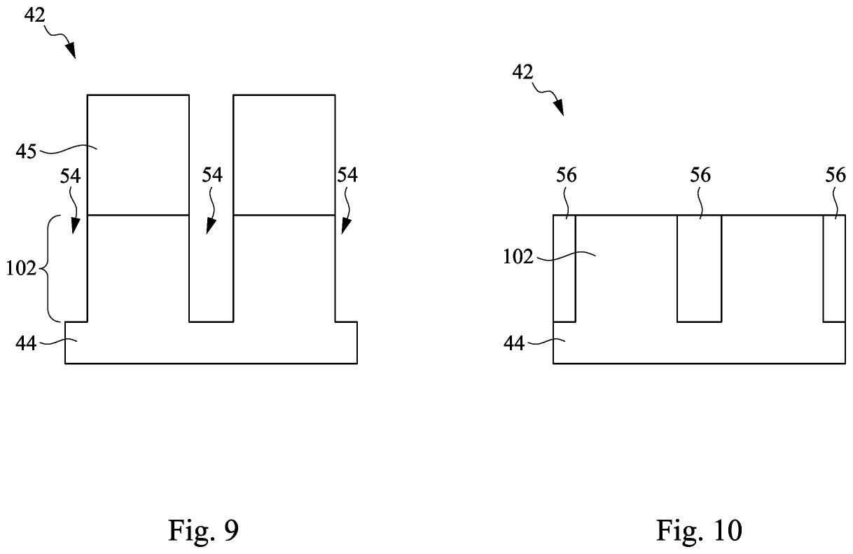

Referring to FIG. 11, the STI regions 56 are recessed, so that the top portions of semiconductor strips 102 protrude higher than top surfaces of the neighboring STI regions 56 to form protruding fins 104. The etching may be performed using a dry etching process or a wet etching process.

Referring to FIGS. 12A-12C, a dummy gate stack 58 is formed on top surfaces and sidewalls of the protruding fins 104. The dummy gate stack 58 may include a dummy gate dielectric 60 and a dummy gate electrode 62 over the dummy gate dielectric 60. The dummy gate dielectric 60 may be, for example, silicon oxide, silicon nitride, a combination thereof, or the like, and may be deposited or thermally grown according to acceptable techniques. The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material.

The dummy gate dielectric 60 may further include an interfacial layer (not shown) including silicon oxide. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56. The dummy gate stack 58 also has a lengthwise direction perpendicular to the lengthwise directions of protruding fins 104.

A photoresist layer 66 is formed over the dummy gate stack 58. In some embodiments, a pad layer (not shown) and a hard mask layer (not shown) may be formed between the photoresist layer 66 and the dummy gate stack 58. The pad layer and the hard mask layer have an etch selectivity with respect to the photoresist layer 66. The pad layer may be a silicon oxide layer and the hard mask layer may be a silicon nitride layer, for example. The above discussion of the first additives 116 (see FIG. 2B) of the photoresist composition of the photoresist layer 114 (see FIG. 2A) applies to the photoresist layer 66, unless mentioned otherwise.

In FIG. 13, using the photoresist layer 66 (see FIG. 12C) as a mask, the pattern of the photoresist layer 66 are extended into the dummy gate stack 58 by etching, using one or more suitable etchants. In some embodiments, the photoresist layer 66 is removed after etching the dummy gate stack 58 by using a suitable photoresist stripper solvent or by a photoresist ashing operation. As discussed previously with regard to FIGS. 2A to 4F, due to the photoresist layer 66 deposited by the photoresist composition including the one or more first additives 116, the photoresist layer 66 can have enhanced etch resistance for the etch process. That is, during the etch process performed to the dummy gate stack 58, an undesired collapse or deformation of the photoresist layer 66 may be prevented. Therefore, the photoresist layer 66 can be prevented from failure of feature fidelity during the etch process, and an extensive process window can be accomplished.

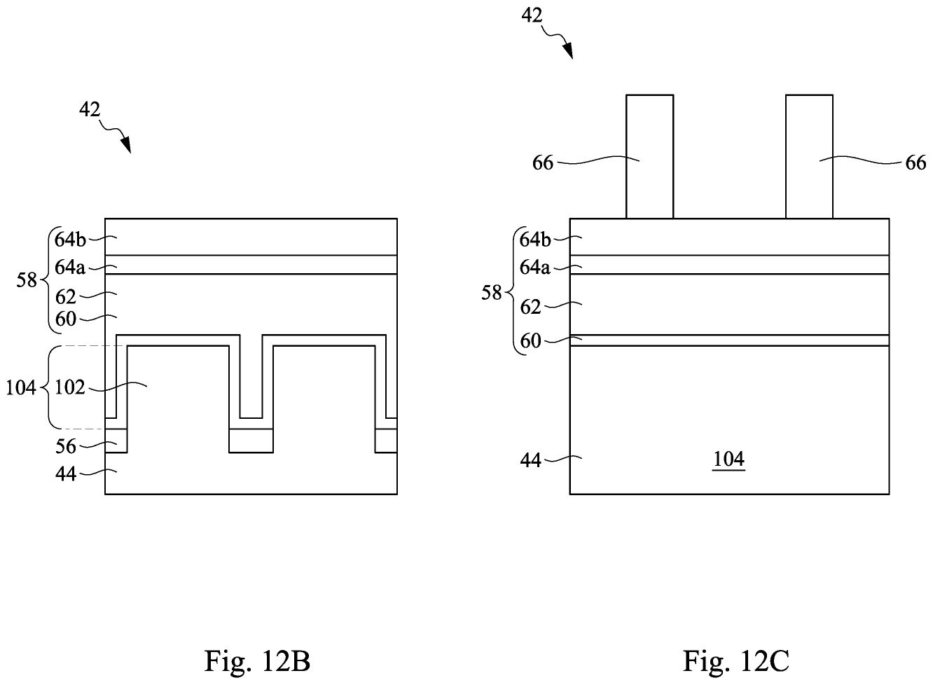

Next, as illustrated in FIG. 14, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

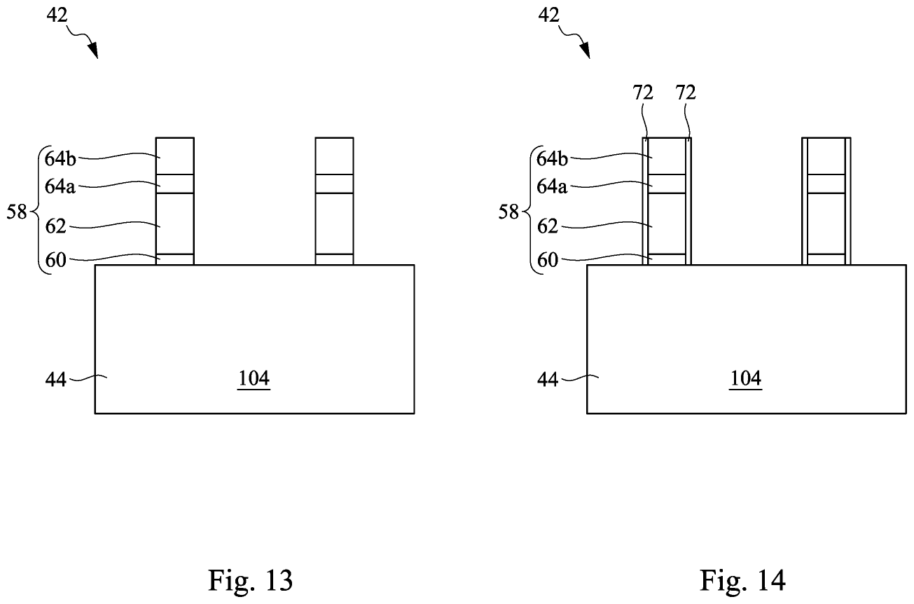

In FIG. 15, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

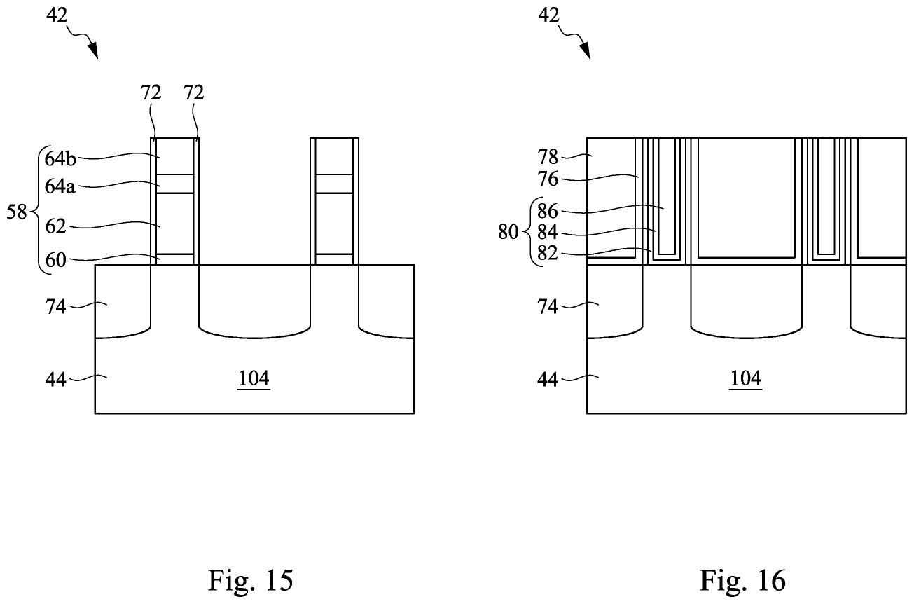

Next, in FIG. 16, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 15) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, replacement gate structures 80 are respectively formed in the gate trenches. The gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 80 forms the gate associated with the three-sides of the channel region provided by the fin 104. Stated another way, each of the gate structures 80 wraps around the fin 104 on three sides. In various embodiments, the high-k/metal gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/metal gate structures 80 may include a metal, metal alloy, or metal silicide. Formation of the high-k/metal gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 84 may include work function metals to provide a suitable work function for the high-k/metal gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that the photoresist layer includes one or more first additives, and thus the photoresist layer can have enhanced etch resistance for the etch process. Another advantage is that during the etch process performed to the target layer, an undesired collapse or deformation of the photoresist layer may be prevented. Yet another advantage is that the photoresist layer can be prevented from failure of feature fidelity during the etch process, and an extensive process window can be accomplished.

In some embodiments, a photoresist composition comprises a solvent, a polymer and a first additive. The polymer is dissolved in the solvent. The first additive is dissolved in the solvent. The first additive is made of a core structure and one or more radical-active functional groups connected to the core structure. In some embodiments, the core structure of the first additive is a linear, branch, cyclic alkyl group, aromatic, electron-withdrawing and electron-donating moieties, or a combination thereof. In some embodiments, the one or more radical-active functional groups of the first additive include double bonds, triple bonds, or a combination thereof. In some embodiments, the one or more radical-active functional groups of the first additive are embedded in a linear, branch, or cyclic alkyl moiety. In some embodiments, the first additive of the photoresist composition is represented by one of following structures:

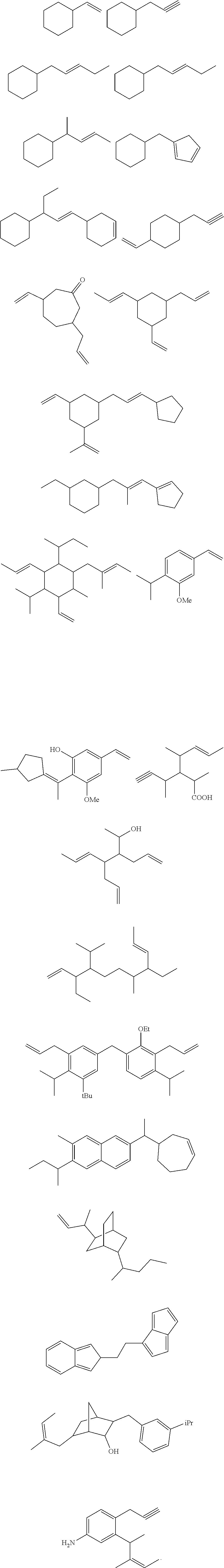

In some embodiments, the core structure of the first additive is made of a cation and an anion connected to the cation. In some embodiments, the one or more radical-active functional groups are connected to the cation of the core structure. In some embodiments, the one or more radical-active functional groups are connected to the anion of the core structure. In some embodiments, the one or more radical-active functional groups have a first group connected to the cation of the core structure and a second group connected to the anion of the core structure. In some embodiments, the cation of the core structure is linear, branch, cyclic alkyl group, aromatic, electron-withdrawing and electron-donating moieties, or a combination thereof. In some embodiments, the anion of the core structure is linear, branch, cyclic alkyl group, aromatic, electron-withdrawing and electron-donating moieties, or a combination thereof. In some embodiments, the first additive of the photoresist composition is represented by one of following structures:

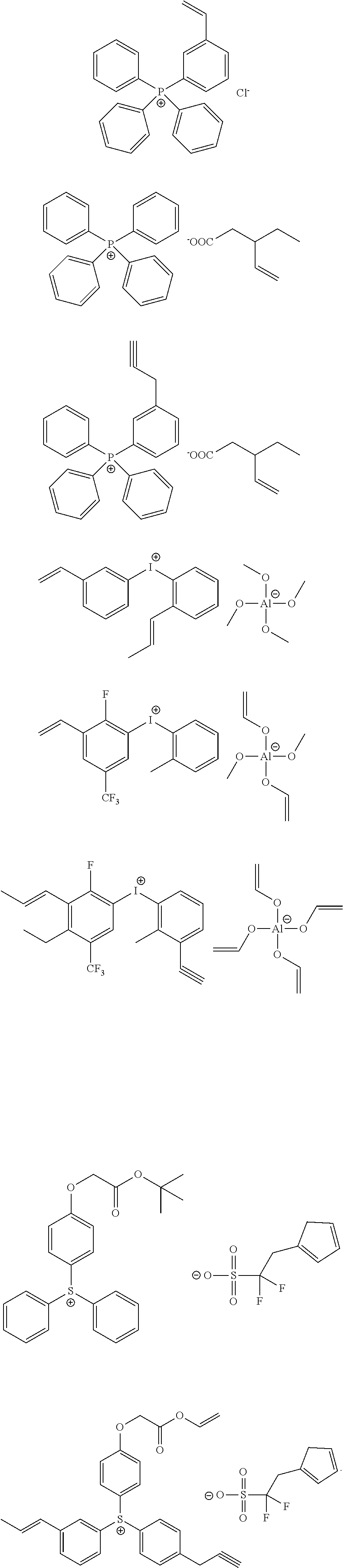

In some embodiments, a lithography method comprises the following steps. A target layer is formed over a substrate. A photoresist composition is deposited over the target layer to form a photoresist layer. The photoresist composition comprises a solvent, a polymer and a first additive. The polymer is dissolved in the solvent. The first additive is dissolved in the solvent. The first additive is made of a core structure and one or more radical-active functional groups connected to the core structure. The photoresist layer is exposed. The photoresist layer is developed. The target layer is etched by using the photoresist layer as an etch mask. In some embodiments, the one or more radical-active functional groups of the first additive are embedded in a linear, branch, or cyclic alkyl moiety. In some embodiments, the first additive of the photoresist composition is represented by one of following structures:

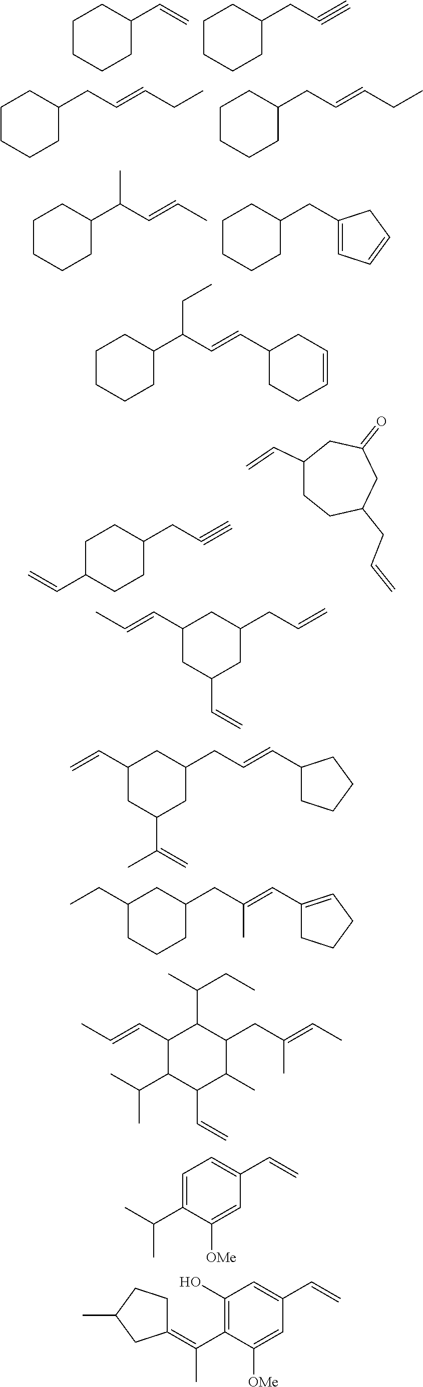

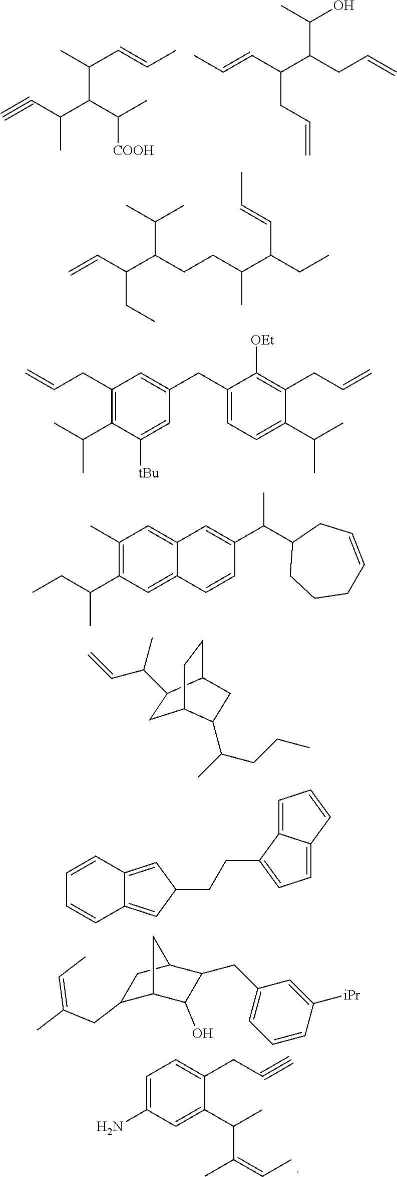

In some embodiments, a lithography method comprises the following steps. A target layer is formed over a substrate. A photoresist composition is deposited over the target layer to form a photoresist layer. The photoresist composition comprises a polymer comprising a polymer backbone and an acid cleavable acid labile group (ALG) bonded to the polymer backbone, and a first additive made of a core structure and one or more radical-active functional groups connected to the core structure. The photoresist layer is exposed. The photoresist layer is developed. The target layer is etched by using the photoresist layer as an etch mask. In some embodiments, the core structure of the first additive is made of a cation and an anion connected to the cation. In some embodiments, the one or more radical-active functional groups has a first group connected to the cation of the core structure, and a second group connected to the anion of the core structure. In some embodiments, one of the cation and the anion of the core structure is linear, branch, cyclic alkyl group, aromatic, electron-withdrawing and electron-donating moieties, or a combination thereof. In some embodiments, the first additive of the photoresist composition is represented by one of following structures:

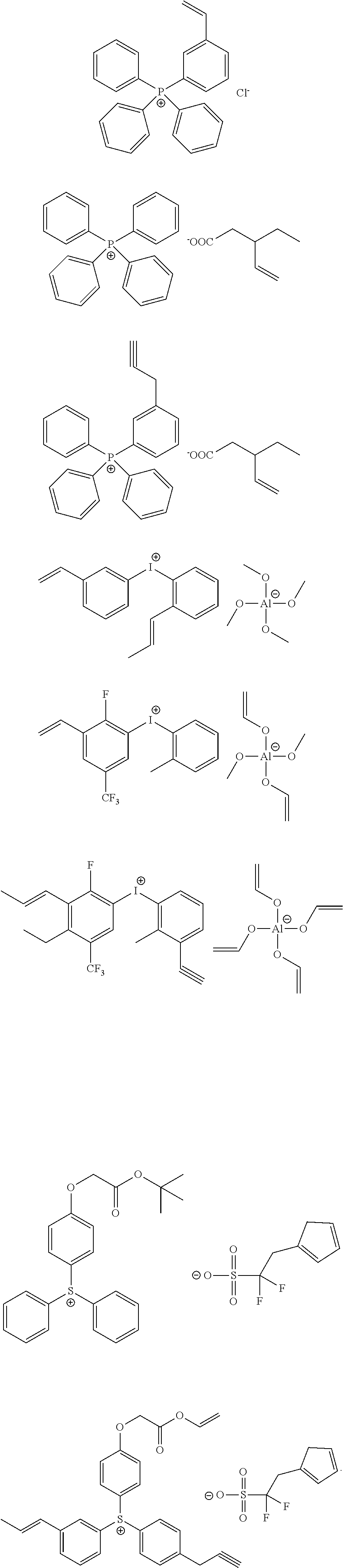

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist composition, comprising:
a solvent;
a polymer dissolved in the solvent; and
a first additive dissolved in the solvent, wherein the first additive is made of a core structure and one or more radical-active functional groups connected to the core structure.

2. The photoresist composition of claim 1, wherein the core structure of the first additive is a linear, branch, cyclic alkyl group, aromatic, electron-withdrawing and electron-donating moieties, or a combination thereof.

3. The photoresist composition of claim 1, wherein the one or more radical-active functional groups of the first additive include double bonds, triple bonds, or a combination thereof.

4. The photoresist composition of claim 3, wherein the one or more radical-active functional groups of the first additive are embedded in a linear, branch, or cyclic alkyl moiety.

5. The photoresist composition of claim 1, wherein the first additive of the photoresist composition is represented by one of following structures:

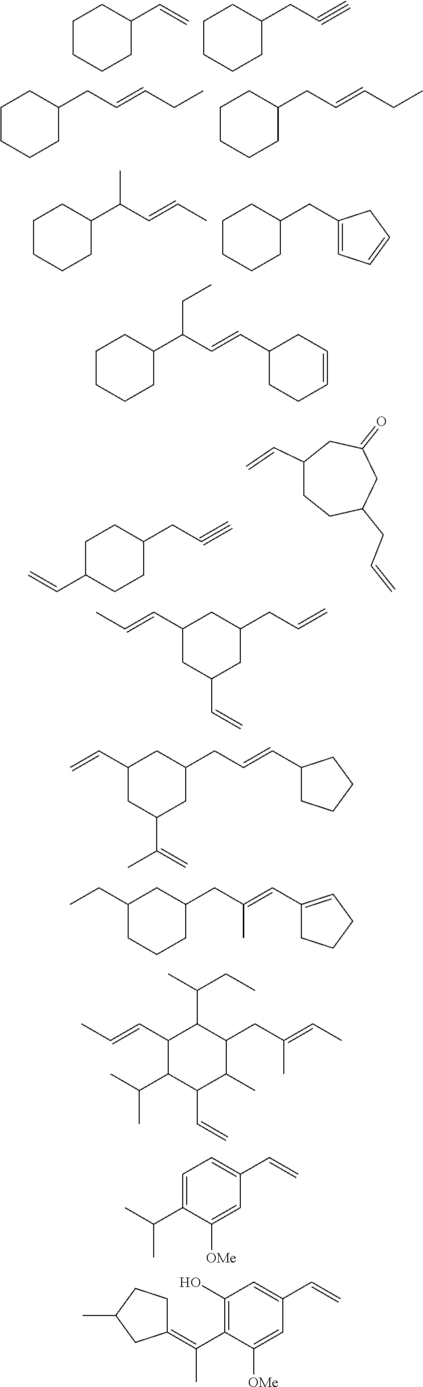

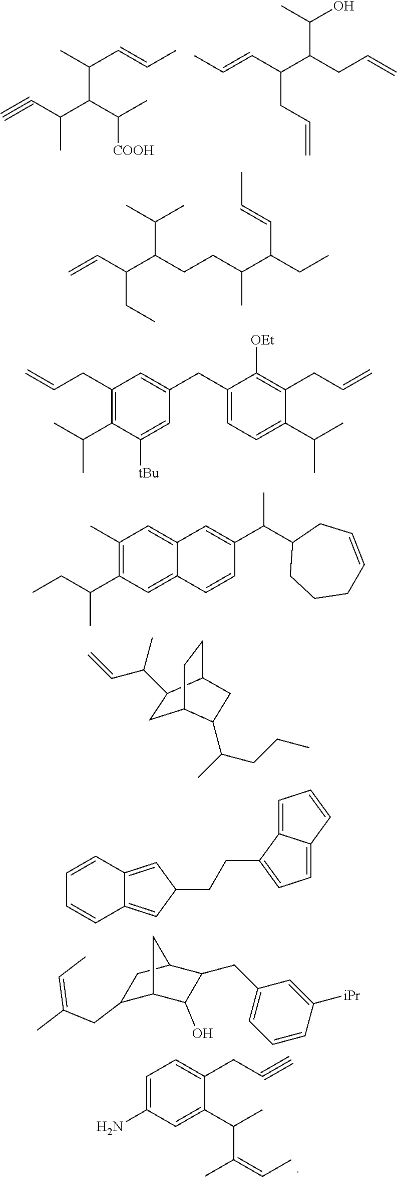

6. The photoresist composition of claim 1, wherein the core structure of the first additive is made of:
a cation; and
an anion connected to the cation.

7. The photoresist composition of claim 6, wherein the one or more radical-active functional groups are connected to the cation of the core structure.

8. The photoresist composition of claim 6, wherein the one or more radical-active functional groups are connected to the anion of the core structure.

9. The photoresist composition of claim 6, wherein the one or more radical-active functional groups have:
a first group connected to the cation of the core structure; and
a second group connected to the anion of the core structure.

10. The photoresist composition of claim 6, wherein the cation of the core structure is linear, branch, cyclic alkyl group, aromatic, electron-withdrawing and electron-donating moieties, or a combination thereof.

11. The photoresist composition of claim 6, wherein the anion of the core structure is linear, branch, cyclic alkyl group, aromatic, electron-withdrawing and electron-donating moieties, or a combination thereof.

12. The photoresist composition of claim 6, wherein the first additive of the photoresist composition is represented by one of following structures:

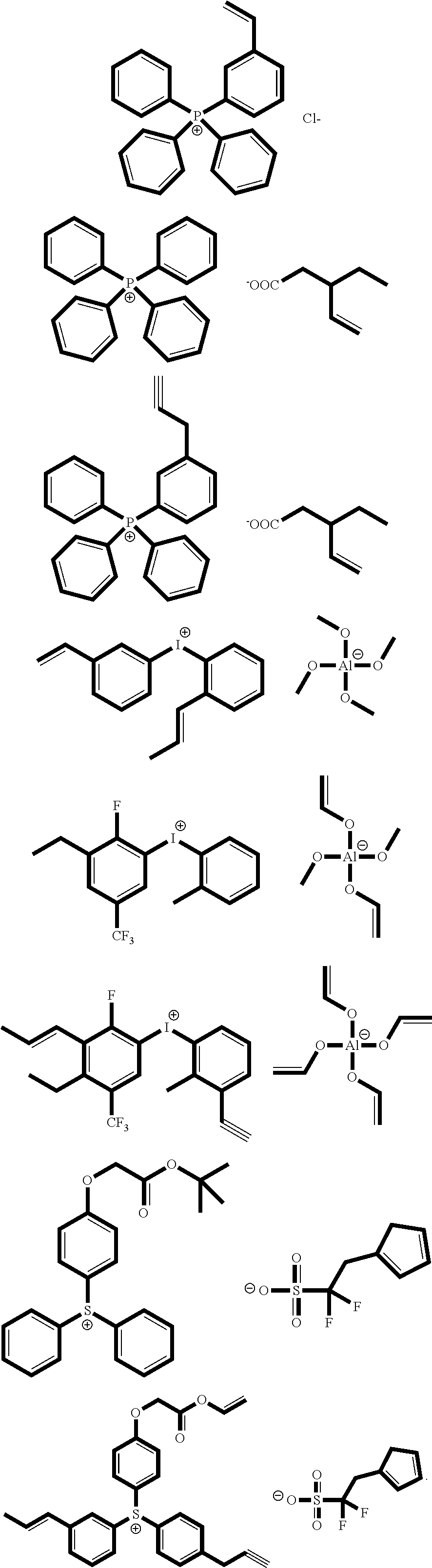

13. A lithography method, comprising:
forming a target layer over a substrate;
depositing a photoresist composition over the target layer to form a photoresist layer, wherein the photoresist composition comprises:
a solvent;
a polymer dissolved in the solvent; and
a first additive dissolved in the solvent, wherein the first additive is made of a core structure and one or more radical-active functional groups connected to the core structure;
exposing the photoresist layer;
developing the photoresist layer; and
etching the target layer by using the photoresist layer as an etch mask.

14. The lithography method of claim 13, wherein the one or more radical-active functional groups of the first additive are embedded in a linear, branch, or cyclic alkyl moiety.

15. The lithography method of claim 13, wherein the first additive of the photoresist composition is represented by one of following structures:

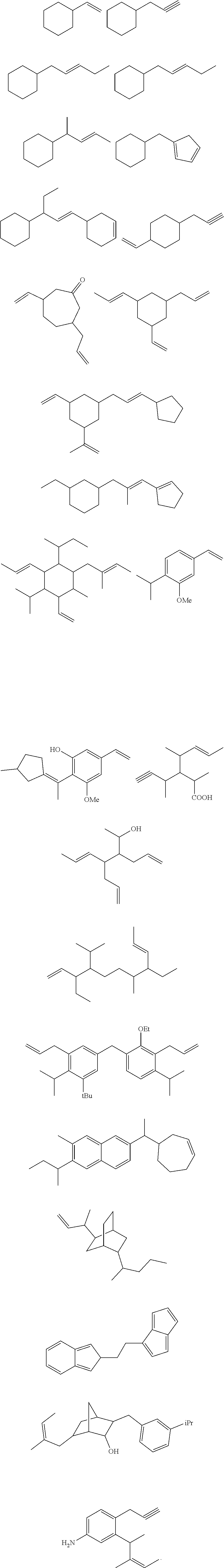

16. A lithography method, comprising:
forming a target layer over a substrate;
depositing a photoresist composition over the target layer to form a photoresist layer, wherein the photoresist composition comprises:
a polymer comprising a polymer backbone and an acid cleavable acid labile group (ALG) bonded to the polymer backbone; and
a first additive made of a core structure and one or more radical-active functional groups connected to the core structure;
exposing the photoresist layer;
developing the photoresist layer; and
etching the target layer by using the photoresist layer as an etch mask.

17. The lithography method of claim 16, wherein the core structure of the first additive is made of:
a cation; and
an anion connected to the cation.

18. The lithography method of claim 17, wherein the one or more radical-active functional groups has:
a first group connected to the cation of the core structure; and
a second group connected to the anion of the core structure.

19. The lithography method of claim 17, wherein one of the cation and the anion of the core structure is linear, branch, cyclic alkyl group, aromatic, electron-withdrawing and electron-donating moieties, or a combination thereof.

20. The lithography method of claim 16, wherein the first additive of the photoresist composition is represented by one of following structures: [chemical structure]
